(19) United States
(12) Patent Application Publication
(10) Pub. No.: US 2021/0381107 A1
(43) Pub. Date: Dec. 9, 2021

(54) MATERIAL DEPOSITION SYSTEMS, AND RELATED METHODS AND MICROELECTRONIC DEVICES

(71) Applicant: Micron Technology, Inc., Boise, ID (US)

(72) Inventors: John A. Smythe, Boise, ID (US); Gurtej S. Sandhu, Boise, ID (US); Sumeet C. Pandey, Boise, ID (US); Michael E. Koltonski, Boise, ID (US)

(21) Appl. No.: 16/891,687

(22) Filed: Jun. 3, 2020

(51) Int. Cl. C23C 16/503; C23C 16/32; C23C 16/38

(52) U.S. Cl. CPC C23C 16/503; C23C 16/38; C23C 16/32

(57) ABSTRACT

A material deposition system comprises a precursor source and a chemical vapor deposition apparatus in selective fluid communication with the precursor source. The precursor source configured to contain at least one metal-containing precursor material in one or more of a liquid state and a solid state. The chemical vapor deposition apparatus comprises a housing structure, a distribution manifold, and a substrate holder. The housing structure is configured and positioned to receive at least one feed fluid stream comprising the at least one metal-containing precursor material. The distribution manifold is within the housing structure and is in electrical communication with a signal generator. The substrate holder is within the housing structure, is spaced apart from the distribution assembly, and is in electrical communication with an additional signal generator. A microelectronic device and methods of forming a microelectronic device also described.

### TECHNICAL FIELD

The disclosure, in various embodiments, relates generally to the field of microelectronic device design and fabrication. More specifically, the disclosure relates to material deposition systems, and to related methods and microelectronic devices.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One approach used to achieve increased integration density involves reducing the lateral footprint of individual features by increasing the aspect ratio (i.e., ratio of vertical height to horizontal width or diameter) of the individual features and the proximity of adjacent features. Unfortunately, conventional methods and systems employed to form relatively higher aspect ratio features require relatively thicker depositions of conventional hard mask material(s) to preserve the conventional hard mask material(s) through the completion of etching acts, which can negatively impact etch rates (e.g., at bottom of the structures) and limit practicable features heights. In addition, conventional hard mask materials facilitating relatively reduced thicknesses can be difficult to form and/or process (e.g., requiring complex and costly processing methodologies).

A need, therefore, exists for new methods and systems for forming microelectronic devices, such as microelectronic devices including high aspect ratio features, as well as for new microelectronic devices formed using the methods and systems.

### BRIEF DESCRIPTION OF THE DRAWINGS

FIG. 1 is a simplified schematic view of a material deposition system, in accordance with an embodiment of the disclosure.

FIG. 2 is a simplified partial cross-sectional view of a microelectronic device structure formed using the material deposition system shown in FIG. 1, in accordance with embodiments of the disclosure.

### DETAILED DESCRIPTION

The following description provides specific details, such as material compositions and processing conditions (e.g., temperatures, pressures, flow rates, etc.) in order to provide a thorough description of embodiments of the disclosure. However, a person of ordinary skill in the art will understand that the embodiments of the disclosure may be practiced without necessarily employing these specific details. Indeed, the embodiments of the disclosure may be practiced in conjunction with conventional systems and methods employed in the industry. In addition, only those process components and acts necessary to understand the embodiments of the present disclosure are described in detail below. A person of ordinary skill in the art will understand that some process components (e.g., pipelines, line filters, valves, temperature detectors, flow detectors, pressure detectors, and the like) are inherently disclosed herein and that adding various conventional process components and acts would be in accord with the disclosure. Moreover, the description provided below does not form a complete process flow for manufacturing a microelectronic device. The structures described below do not form a complete microelectronic device. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the term “substrate” means and includes a base material or construction upon which additional materials are formed. The substrate may be a semiconductor substrate, a base semiconductor layer on a supporting structure, a metal electrode, or a semiconductor substrate having one or more layers, structures or regions formed thereon. The substrate may be a conventional silicon substrate or other bulk substrate comprising a layer of semiconductive material. As used herein, the term “bulk substrate” means and includes not only silicon wafers, but also silicon-on-insulator (SOI) substrates, such as silicon-on-sapphire (SOS) substrates and silicon-on-glass (SOG) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped. By way of non-limiting example, a substrate may comprise at least one of silicon, silicon dioxide, silicon with native oxide, silicon nitride, a carbon-containing silicon nitride, glass, semiconductor, metal oxide, metal, titanium nitride, carbon-containing titanium nitride, tantalum, tantalum nitride, carbon-containing tantalum nitride, niobium, niobium nitride, carbon-containing niobium nitride, molybdenum, molybdenum nitride, carbon-containing molybdenum nitride, tungsten, tungsten nitride, carbon-containing tungsten nitride, copper, cobalt, nickel, iron, aluminum, and a noble metal.

As used herein, a “memory device” means and includes a microelectronic device exhibiting, but not limited to, memory functionality.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

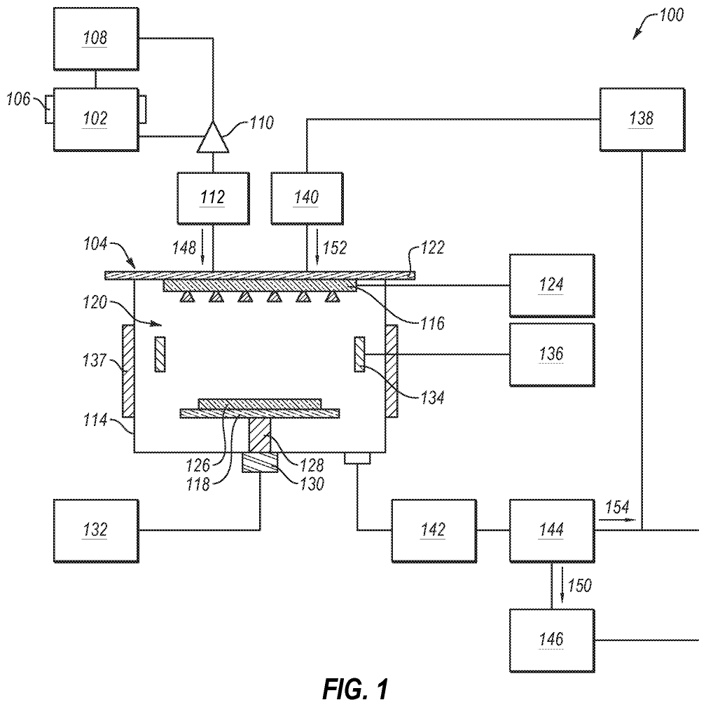

An embodiment of the disclosure will now be described with reference to FIG. 1, which schematically illustrates a material deposition system 100 (e.g., a plasma enhanced chemical vapor deposition (PECVD) system). The material deposition system 100 may be used to produce a microelectronic device structure including a metal-containing material (e.g., a metal-containing carbon material, a metal-containing boron material, a metal-containing boron-carbon material) through PECVD, as described in further detail below. As shown in FIG. 1, the material deposition system 100 may include at least one precursor source 102, and at least one PECVD apparatus 104 in selective (i.e., subject to operator or system control) fluid communication with the precursor source 102. The material deposition system 100 may further include additional apparatuses operatively associated with one or more of the precursor source 102 and the PECVD apparatus 104, as described in further detail below.

The precursor source 102 comprises at least one apparatus (e.g., containment vessel) configured and operated to contain (e.g., store) and/or produce at least one precursor material to be used by the PECVD apparatus 104 to produce a metal-containing material (e.g., a metal-containing carbon material, a metal-containing boron material, a metal-containing boron-carbon material). The produced metal-containing material may, for example, be used as a hard mask material to form a microelectronic device, as described in further detail below. In some embodiments, the precursor material of the precursor source 102 comprises at least one metal-containing precursor material, such as one or more of a tantalum (Ta)-containing precursor material, a hafnium (Hf)-containing precursor material, a zinc (Zn)-containing precursor material, a vanadium (V)-containing precursor material, an iridium (Ir)-containing precursor material, a zirconium (Zr)-containing precursor material, a tungsten (W)-containing precursor material, a niobium (Nb)-containing precursor material, and a scandium (Sc)-containing precursor material.

The precursor source 102 may be configured and operated to contain one or more of at least one liquid precursor material (e.g., at least one liquid metal-containing precursor material) and at least one flowable solid precursor material (e.g., at least one flowable solid metal-containing precursor material). In some embodiments, the precursor source 102 is configured and operated to contain one or more liquid metal-containing precursor materials. In further embodiments, the precursor source 102 is configured and operated to contain one or more flowable solid metal-containing precursor materials.

As a non-limiting example, the precursor source 102 may comprise a storage vessel configured and operated to hold a liquid material comprising one or more of a liquid Ta-containing precursor material, a liquid Hf-containing precursor material, a liquid Zn-containing precursor material, a liquid V-containing precursor material, a liquid Ir-containing precursor material, a liquid Zr-containing precursor material, a liquid W-containing precursor material, a liquid Nb-containing precursor material, and a liquid Sc-containing precursor material. For example, the precursor source 102 may comprise a storage vessel configured and operated to hold a liquid Ta-containing precursor material including a liquid state of one or more of tantalum (V) ethoxide (Ta(OC₂H₅)₅, melting point (mp)=21° C.); tris(diethylamido)(tert-butylimido)tantalum(V) ((CH₃)₃CNTa(N(C₂H₅)₂)₃); tris(ethylmethylamido)(tert-butylimido)tantalum(V) (C₁₃H₃₃N₄Ta), tantalum pentafluoride (TaF₅, mp=96.8° C.); tantalum pentachloride (TaCl₅, mp=216° C.); and pentakis(dimethylamino)tantalum(V) ((Ta(N(CH₃)₂)₅, mp=100° C.). As another example, the precursor source 102 may comprise a storage vessel configured and operated to hold a liquid Hf-containing precursor material including a liquid state of one or more of hafnium(IV) tert-butoxide (Hf[OC(CH₃)₃]₄); tetrakis(diethylamido)hafnium(IV) ([(CH₂CH₃)₂N]₄Hf); tetrakis(ethylmethylamido)hafnium(IV) ([(CH₃)(C₂H₅)N]₄Hf); bis(trimethylsilyl)amidohafnium(IV) chloride ([[(CH₃)₃Si]₂N]₂HfCl₂, mp=44° C.); and dimethylbis(cyclopentadienyl)hafnium(IV) ((C₅H₅)₂Hf(CH₃)₂, mp=118° C.). As another example, the precursor source 102 may comprise a storage vessel configured and operated to hold a liquid Zn-containing precursor material including a liquid state of one or more of diethylzinc ((C₂H₅)₂Zn); and bis(pentafluorophenyl)zinc ((C₆F₅)₂Zn, mp=105° C.). As another example, the precursor source 102 may comprise a storage vessel configured and operated to hold a liquid V-containing precursor material including a liquid state of one or more of vanadium(V) oxytriisopropoxide (OV(OCH(CH₃)₂)₃); vanadium pentaflouride (VF₅, mp=19.5° C.); vanadium tetrachloride (VCl₄, mp=−20.5° C.); and bis(cyclopentadienyl)vanadium(II) (V(C₅H₅)₂, mp=167° C.). As another example, the precursor source 102 may comprise a storage vessel configured and operated to hold a liquid Zr-containing precursor material including a liquid state of one or more of tetrakis(ethylmethylamido)zirconium(IV) (Zr(NCH₃C₂H₅)₄); bis(cyclopentadienyl)zirconium(IV) dihydride (C₁₀H₁₂Zr, mp=300° C.); dimethylbis(pentamethylcyclopentadienyl)zirconium(IV) (C₂₂H₃₆Zr, mp=206° C.); and tetrakis(dimethylamido)zirconium(IV) ([(C₂H₅)₂N]₄Zr, mp=60° C.). As another example, the precursor source 102 may comprise a storage vessel configured and operated to hold a liquid W-containing precursor material including a liquid state of one or more of bis(tert-butylimino)bis(dimethylamino)tungsten(VI) (((CH₃)₃CN)₂W(N(CH₃)₂)₂); tetracarbonyl(1,5-cyclooctadiene)tungsten(0) (C₁₂H₁₂O₄W, mp=158° C.); and hexacarbonyltungsten (0) (W(CO)₆, mp=150° C.). As another example, the precursor source 102 may comprise a storage vessel configured and operated to hold a liquid Nb-containing precursor material including a liquid state of one or more of tris(diethylamido)(tert-butylimido)niobium (Nb-TBTDEN); ^{t}BuN=Nb(NEt₂)₃; ^{t}BuN=Nb(NMeEt)₃; ^{t}amylN=Nb(OtBu)₃; niobium (V) ethoxide (Nb(OCH₂CH₃)₅, mp=6° C.); niobium pentaflouride (NbF₅, mp=73° C.); niobium pentachloride (NbCl₅, mp=205° C.); and niobium (V) ethoxide (Nb(OCH₂CH₃)₅, mp=6° C.). As another example, the precursor source 102 may comprise a storage vessel configured and operated to hold a liquid Sc-containing precursor material including a liquid state of one or more of Sc(thd)₃ (thd=2,2,6,6-tetramethyl-3,5-heptanedione); ((C₅H₅)₃Sc, mp=240° C.); Sc(MeCp)₂(Me2pz) (MeCp=methylcyclopentadienyl, Me2pz=3,5-dimethylpyrazolate); and scandium tris(N,N-diisopropylacetamidinate).

As another non-limiting example, the precursor source 102 may comprise a storage vessel configured and operated to hold a powder comprising solid particles of one or more metal-containing precursor materials, such as particles of one or more of a solid Ta-containing precursor material, a solid Hf-containing precursor material, a solid Zn-containing precursor material, a solid V-containing precursor material, a solid Ir-containing precursor material, a solid Zr-containing precursor material, a solid W-containing precursor material, a solid Nb-containing precursor material, and a solid Sc-containing precursor material. For example, the precursor source 102 may comprise a storage vessel configured and operated to hold a Ta-containing precursor material including solid particles of one or more of TaF₅, TaCl₅, and (Ta(N(CH₃)₂)₅. As another example, the precursor source 102 may comprise a storage vessel configured and operated to hold a Hf-containing precursor material including solid particles of one or more of [[(CH₃)₃Si]₂N]₂HfCl₂ and (C₅H₅)₂Hf(CH₃)₂. As another example, the precursor source 102 may comprise a storage vessel configured and operated to hold a Zn-containing precursor material including solid particles of (C₆F₅)₂Zn. As another example, the precursor source 102 may comprise a storage vessel configured and operated to hold a V-containing precursor material including solid particles of V(C₅H₅)₂. As another example, the precursor source 102 may comprise a storage vessel configured and operated to hold a Zr-containing precursor material including solid particles of one or more of C₁₀H₁₂Zr, C₂₂H₃₆Zr, and [(C₂H₅)₂N]₄Zr. As another example, the precursor source 102 may comprise a storage vessel configured and operated to hold a W-containing precursor material including solid particles of one or more of C₁₂H₁₂O₄W and W(CO)₆. As another example, the precursor source 102 may comprise a storage vessel configured and operated to hold an Nb-containing precursor material including solid particles of one or more of NbF₅ and NbCl₅. As another example, the precursor source 102 may comprise a storage vessel configured and operated to hold an Sc-containing precursor material including solid particles of one or more of Sc(thd)₃, (C₅H₅)₃Sc, Sc(MeCp)₂(Me2pz), and scandium tris(N,N-diisopropylacetamidinate).

The material deposition system 100 may include a single (i.e., only one) precursor source 102, or may include multiple (i.e., more than one) precursor sources 102. If the material deposition system 100 includes multiple precursor sources 102, the precursor sources 102 may be substantially similar to one another (e.g., may exhibit substantially similar components, component sizes, component shapes, component material compositions, component material distributions, component positions, component orientations) and may be operated under substantially similar conditions (e.g., substantially similar temperatures, pressures, flow rates), or at least one of the precursor sources 102 may be different (e.g., exhibit one or more of different components, different component sizes, different component shapes, different component material compositions, different component material distributions, different component positions, different component orientations) than at least one other of the precursor sources 102 and/or may be operated under different conditions (e.g., different temperatures, different pressures, different flow rates, etc.) than at least one other of the precursor sources 102. For example, the material deposition system 100 may include at least two (2) precursor sources 102, wherein one of the precursor sources 102 is configured to contain a first metal-containing precursor material (e.g., a first liquid metal-containing precursor material, a first flowable solid metal-containing precursor material), and another of the precursor sources 102 is configured to contain a second, different metal-containing precursor material (e.g., a second liquid metal-containing precursor material, a second flowable solid metal-containing precursor material). In some embodiments, two or more precursor sources 102 are provided in parallel with one another within the material deposition system 100. In additional embodiments, two or more precursor sources 102 are provided in series with one another within the material deposition system 100.

With continued reference to FIG. 1, the material deposition system 100 may, optionally, further include at least one heating apparatus 106 operatively associated with the precursor source 102. The heating apparatus 106, if present, may comprise at least one apparatus (e.g., one or more of a heat exchanger, such as a tube-in-tube heat exchanger and/or a shell-and-tube heat exchanger; a combustion heater; a nuclear heater; a sonication heater; an electrical resistance heater; an inductive heater; an electromagnetic heater, such as an infrared heater and/or a microwave heater) configured and operated to heat at least a portion of the precursor source 102. The heating apparatus 106 may be employed to heat or maintain precursor material of the precursor source 102 at a desired temperature, such as a temperature facilitating flowability of the precursor material. In some embodiments, such as some embodiments wherein the precursor material of the precursor source 102 comprises one or more of a liquid precursor material and a solid (e.g., powderized) precursor material, the heating apparatus 106 is included in the material deposition system 100 and is configured and positioned to heat the precursor source 102. In some such embodiments, lines (e.g., piping, tubes) extending from and between the precursor source 102 and the PECVD apparatus 104 are thermally insulated to maintain a desired temperature of at least one feed fluid stream directed from the precursor source 102 to the PECVD apparatus 104. In additional embodiments, such as some embodiments wherein the precursor material of the precursor source 102 does not require supplemental heating, the heating apparatus 106 is omitted from the material deposition system 100.

Still referring to FIG. 1, the material deposition system 100 may further include at least one carrier gas source 108 in selective fluid communication with the precursor source 102. The carrier gas source 108 may comprise at least one apparatus (e.g., at least one pressure vessel) configured and operated to hold (e.g., contain, store) a volume of carrier gas. The carrier gas may, for example, comprise at least one inert gas (e.g., at least one noble gas), such as one or more of helium (He) gas, neon (Ne) gas, and argon (Ar) gas. Carrier gas of the carrier gas source 108 may be employed as a suspension medium for one or more precursor materials (e.g., liquid metal-containing precursor materials, solid metal-containing precursor materials) contained within precursor source 102, as described in further detail below.

The carrier gas source 108, if present, may be operatively associated with the precursor source 102 in a manner facilitating interaction (e.g., mixing) of carrier gas from the carrier gas source 108 with precursor material from the precursor source 102 upstream of, at, and/or within the PECVD apparatus 104. As a non-limiting example, the carrier gas source 108 may be provided upstream of and in selective fluid communication with the precursor source 102, such that carrier gas from the carrier gas source 108 may be mixed with precursor material of the precursor source 102 within and/or downstream of the precursor source 102. In some embodiments, the carrier gas source 108 is configured and positioned such that carrier gas exiting the carrier gas source 108 is mixed with precursor material of the precursor source 102 within precursor source 102. For example, the carrier gas may be delivered into and mix with the precursor material within at least one internal chamber of the precursor source 102. In additional embodiments, the carrier gas source 108 and the precursor source 102 are each fluidly coupled to an optional mixing apparatus 110 downstream of the precursor source 102 and upstream of the PECVD apparatus 104. Carrier gas from the carrier gas source 108 and precursor material from the precursor source 102 may each be fed (e.g., flowed, pumped) into the mixing apparatus 110, wherein they may be combined ahead of the PECVD apparatus 104. In some embodiments, the mixing apparatus 110 is configured and operated to from form a gaseous mixture including discrete portions (e.g., discrete liquid droplets, discrete solid particles) of the precursor material dispersed and entrained within the inert gas. For example, the mixing apparatus 110 may comprise an injector apparatus including an atomizing nozzle.

With continued reference to FIG. 1, optionally, the material deposition system 100 may further include at least one ionization device 112 downstream of the precursor source 102 and upstream of the PECVD apparatus 104. If present, the ionization device 112 may be configured and operated expose precursor material from the precursor source 102 to an ionized field to modify (e.g., ionize, react) precursors in a manner that promotes or facilitates desired material formation reactions (e.g., carbide formation reactions, boride formation reactions) within the PECVD apparatus 104. The configuration and parameters of the ionization device 112 may be tailored to desired influence on one or more precursor material(s). As a non-limiting example, the ionization device 112 may employ a laser energy source outputting a predetermined wavelength of electromagnetic energy selected to break specific chemical bonds of one or more metal-containing precursors of the precursor material. As another non-limiting example, the ionization device 112 may employ a microwave energy source facilitating ionization of one or more metal-containing precursors of the precursor material in a predetermined manner. In additional embodiments, the ionization device 112 is omitted (e.g., absent) from the material deposition system 100.

With continued reference to FIG. 1, the PECVD apparatus 104 is positioned downstream of the precursor source 102. The PECVD apparatus 104 includes a housing structure 114, and each of at least one distribution assembly 116 (e.g., distribution manifold, showerhead assembly) and at least one substrate holder 118 within the housing structure 114. The distribution assembly 116 and the substrate holder 118 may be spaced apart (e.g., separated, distanced) from one another within housing structure 114. The PECVD apparatus 104 may further include additional features (e.g., additional structures, additional devices), as described in further detail below.

The housing structure 114 of the PECVD apparatus 104 exhibits at least one inlet configured and positioned to receive at least one feed (e.g., influent) fluid stream comprising precursor material from the precursor source 102 (and, optionally carrier gas from the carrier gas source 108), and at least outlet positioned to direct at least one exhaust (e.g., effluent) fluid stream comprising reaction byproducts and unreacted materials from the PECVD apparatus 104. The housing structure 114 may at least partially define at least one internal chamber 120 of the PECVD apparatus 104. The internal chamber 120 may surround and hold the distribution assembly 116 and the substrate holder 118 of the PECVD apparatus 104. The housing structure 114 may further include one or more sealable structures facilitating access to the internal chamber 120 to permit the insertion and removal of structures (e.g., substrates) into the internal chamber 120. By way of non-limiting example, as shown in FIG. 1, the housing structure 114 may exhibit a removable and sealable lid 122. The housing structure 114 may be formed of and include any material (e.g., metal, alloy, glass, polymer, ceramic, composite, combination thereof) compatible with the operating conditions (e.g., temperatures, pressures, material exposures, generated electrical fields, generated magnetic fields) of the PECVD apparatus 104. In some embodiments, the housing structure 114 is formed of and includes stainless steel.

The distribution assembly 116 is configured and positioned to direct one or more feed fluid stream(s) including precursor material from the precursor source 102 and/or derivatives (e.g., ions) formed from the precursor material (and, optionally carrier gas from the carrier gas source 108) into the internal chamber 120 of the PECVD apparatus 104. In addition, the distribution assembly 116 may be configured to generate glow discharge upon the application of voltage thereto that may be employed to generate plasma from components of the feed fluid stream(s). The distribution assembly 116 may, for example, serve as an electrode (e.g., a cathode) of the PECVD apparatus 104. As shown in FIG. 1, the distribution assembly 116 may be electrically connected to at least one signal generator 124 of the material deposition system 100. The signal generator 124 may include at least one power source (e.g., a variable direct current (DC) power source, a variable radio frequency (RF) power source). The signal generator 124 may also include additional components, such as at least one waveform modulator having circuitry configured for modulation of the waveform, frequency, and amplitude of output signals.

The substrate holder 118 is configured and positioned to support and temporarily hold at least one substrate 126 thereon or thereover. As shown in FIG. 1, the substrate holder 118 may be mounted on at least one rod structure 128 operatively associated with a motor assembly 130. The rod structure 128 and the motor assembly 130 may be configured and operated to adjust the location of the substrate holder 118 (and, hence, a substrate 126 thereon) between a relatively lower position (e.g., for loading and unloading the substrate 126) and a relatively higher position (e.g., for processing the substrate 126). In addition, the substrate holder 118 may be electrically connected to at least one additional signal generator 132 of the material deposition system 100. The additional signal generator 132 may include at least one additional power source (e.g., DC power source, an RF power source, an alternating current (AC) power source). The additional signal generator 132 may also include additional components, such as at least one waveform modulator having circuitry configured for modulation of the waveform, frequency, and amplitude of output signals. The substrate holder 118 may be configured to generate glow discharge upon the application of voltage thereto that may be employed to generate plasma from the feed fluid stream(s) received into the internal chamber 120 of the PECVD apparatus 104. The substrate holder 118 may, for example, serve as an additional electrode (e.g., an anode) of the PECVD apparatus 104.

Optionally, the PECVD apparatus 104 may further include at least one coil structure 134 positioned between the distribution assembly 116 and the substrate holder 118 within the internal chamber 120 of the PECVD apparatus 104. The coil structure 134 may be configured and operated to assist in generating and/or maintaining plasma between the distribution assembly 116 and the substrate 126. As described in further detail below, the coil structure 134 may be configured and operated to inductively couple energy into plasma produced within the internal chamber 120 to induce electromagnetic currents in the plasma. The electromagnetic currents may heat the plasma by Ohmic heating to sustain the plasma in a steady state. The electromagnetic currents may also facilitate relatively denser plasma, which may facilitate or enhance ionization of materials of feed fluid stream(s) delivered into the PECVD apparatus 104. As shown in FIG. 1, if present, the coil structure 134 may be electrically connected to at least one further signal generator 136 of the material deposition system 100. The further signal generator 136 may include at least one additional power source (e.g., an RF power source, a DC power source). The further signal generator 136 may also include additional components, such as an impedance-matching network. The coil structure 134 may act as first windings of a transformer. In additional embodiments, the coil structure 134 is omitted (e.g., absent) from the PECVD apparatus 104.

With continued reference to FIG. 1, the material deposition system 100 may, optionally, further include at least one additional heating apparatus 137 operatively associated with the PECVD apparatus 104. The additional heating apparatus 137, if present, may comprise at least one apparatus (e.g., one or more of a heat exchanger, such as a tube-in-tube heat exchanger and/or a shell-and-tube heat exchanger; a combustion heater; a nuclear heater; a sonication heater; an electrical resistance heater; an inductive heater; an electromagnetic heater, such as an infrared heater and/or a microwave heater) configured and operated to heat at least a portion of the PECVD apparatus 104 (e.g., at least a portion of the substrate holder 118, at least a portion of the housing structure 114). The additional heating apparatus 137 may be employed to heat or maintain one or more portions of the PECVD apparatus 104 at a desired temperature, such as a temperature facilitating the formation of at least one metal-containing material (e.g., at least one metal-containing carbon material, at least one metal-containing boron material, at least one metal-containing boron-carbon material) through PECVD using precursor material and/or derivatives (e.g., ions) of precursor material from the precursor source 102. In some embodiments, the additional heating apparatus 137 is configured and positioned to facilitate a temperature within internal chamber 120 of the PECVD apparatus 104 greater than or equal to about 200° C., such as greater than or equal to about 300° C., greater than or equal to about 400° C., or greater than or equal to about 450° C. In additional embodiments, such as some embodiments wherein the precursor material of the precursor source 102, does not require supplemental heating to form a desired metal-containing material through PECVD, the additional heating apparatus 137 is omitted from the material deposition system 100.

Still referring to FIG. 1, optionally, the material deposition system 100 may further include at least one chamber cleaning material source 138 in selective fluid communication with the PECVD apparatus 104. If present, the chamber cleaning material source 138 may be configured and operated to contain at least one chamber cleaning material (e.g., at least one gaseous chamber cleaning material) that may be employed to clean (e.g., remove undesired materials from) the internal chamber 120 of the PECVD apparatus 104. Chamber cleaning material from the chamber cleaning material source 138 may, for example, be delivered into and then removed from the PECVD apparatus 104 to clean the internal chamber 120 of the PECVD apparatus 104 prior to and/or after delivering one or more feed fluid stream(s) including precursor material from the precursor source 102 and/or derivatives (e.g., ions) formed from the precursor material (and, optionally inert gas from the carrier gas source 108) into the internal chamber 120 of the PECVD apparatus 104. In some embodiments, the chamber cleaning material source 138 is configured and operated to contain one or more gaseous chamber cleaning material(s). As a non-limiting example, the chamber cleaning material source 138 may comprise a storage vessel configured and operated to hold a gaseous material comprising one or more of molecular fluorine (F₂), nitrogen trifluoride (NF₃) and sulfur fluoride (SF).

If the material deposition system 100 includes the chamber cleaning material source 138, the material deposition system 100 may, optionally, further include at least one additional ionization device 140 downstream of the chamber cleaning material source 138 and upstream of the PECVD apparatus 104. If present, the additional ionization device 140 be configured and operated expose chamber cleaning material from the chamber cleaning material source 138 to an ionized field to modify (e.g., ionize, react) components thereof before delivery into the PECVD apparatus 104. The configuration and parameters of the additional ionization device 140 (if any) may be tailored to desired influence on chamber cleaning material from the chamber cleaning material source 138. As a non-limiting example, the additional ionization device 140 may employ a laser energy source outputting a predetermined wavelength of electromagnetic energy selected to break specific chemical bonds of one or more components (e.g., molecules, compounds) of the chamber cleaning material. As another non-limiting example, the additional ionization device 140 may employ a microwave energy source facilitating modification of one or more of the components of the chamber cleaning material. As a further non-limiting example, additional ionization device 140 may employ electromagnetic energy within the ultraviolet (UV) spectrum or another spectrum to modify one or more of the components of the chamber cleaning material. Electromagnetic energy may, for example, be radiated toward the chamber cleaning material using one or more slot plane antennae. The configuration and operation of the additional ionization device 140 (if any) may be tailored to the material composition(s) of material(s) within the internal chamber 120 to be removed. For example, the configuration and operation of the additional ionization device 140 (if any) may be tailored to facilitate the formation of chemical species (e.g., reactive fragments, ions, ligands) from the chamber cleaning material able to etch and/or volatilize the material(s) from surfaces within the internal chamber 120.

If present, the additional ionization device 140 may be separate and discrete from the ionization device 112. For example, the additional ionization device 140 may not be configured and positioned to receive and act upon precursor material from the precursor source 102, and the ionization device 112 may not be configured and positioned to receive and act upon chamber cleaning material from the chamber cleaning material source 138. As shown in FIG. 1, in some embodiments, the ionization device 112 and the additional ionization device 140 are each positioned on or over the lid 122 of the PECVD apparatus 104. The additional ionization device 140 may, for example, be spaced apart from the ionization device 112 on the lid 122 of the PECVD apparatus 104. In additional embodiments, one or more of the ionization device 112 (if any) and the additional ionization device 140 (if any) is provided at a different location relative to PECVD apparatus 104 and/or one another, such as a location not on or over the lid 122 of the PECVD apparatus 104. In further embodiments, the additional ionization device 140 is omitted (e.g., absent) from the material deposition system 100.

With continued reference to FIG. 1, optionally, the material deposition system 100 may further include at least one vacuum apparatus 142 operatively associated with at least one outlet of the housing structure 114 of the PECVD apparatus 104. If present, the vacuum apparatus 142 may be configured and operated to assist with the control of pressure within the internal chamber 120 of the PECVD apparatus 104, as well as the removal of reaction byproducts and/or unreacted materials (e.g., unreacted precursor materials, unreacted chamber cleaning materials, unreacted derivatives thereof) from the internal chamber 120 of the PECVD apparatus 104. The vacuum apparatus 142 may be configured and operated to apply negative pressure to the internal chamber 120 of the PECVD apparatus 104. In additional embodiments, the vacuum apparatus 142 is omitted (e.g., absent) from the material deposition system 100.

Still referring to FIG. 1, the material deposition system 100 may further include at least one flow path switching device 144 (e.g., at least one flow path switching valve, at least one bypass valve) downstream of the PECVD apparatus 104 (e.g., downstream of the vacuum apparatus 142). The flow path switching device 144 may be configured and positioned to divert one or more effluent fluid streams exiting the PECVD apparatus 104 to one or more additional apparatuses along different flow paths downstream of the flow path switching device 144. By way of non-limiting example, as shown in FIG. 1, the flow path switching device 144 may be configured and positioned to switchably direct at least one effluent fluid stream exiting the PECVD apparatus 104 to the chamber cleaning material source 138 along a first flow path downstream of the flow path switching device 144 or to an effluent fluid treatment apparatus 146 along a second flow path downstream of the flow path switching device 144. The flow path switching device 144 may, for example, be configured and operated to direct chamber cleaning byproducts and unreacted chamber cleaning materials effectuated during a cleaning operations for the PECVD apparatus 104 to the chamber cleaning material source 138 (and/or to another apparatus associated with retrieval and/or treatment of chamber cleaning material and/or chamber cleaning process byproducts), and to direct reaction byproducts and unreacted precursors effectuated during material deposition (e.g., PECVD) operations for the PECVD apparatus 104 to the effluent fluid treatment apparatus 146.

Still referring to FIG. 1, the effluent fluid treatment apparatus 146 may be positioned downstream of the PECVD apparatus 104 (e.g., downstream of the flow path switching device 144). The effluent fluid treatment apparatus 146 may be configured and operated to treat (e.g., scrub) effluent fluid (e.g., exhaust gases) exiting the PECVD apparatus 104 to at least partially remove one or more materials (e.g., reaction byproducts, unreacted precursor, toxic materials, hazardous materials, pollutants) therefrom. In some embodiments, the effluent fluid treatment apparatus 146 is configured and positioned to remove (e.g., trap, scrub) unreacted metal-containing precursors and/or other desirable materials from at least one effluent fluid stream exiting the PECVD apparatus 104. The effluent fluid treatment apparatus 146 may, for example, comprise one or more of a precursor trap apparatus and a scrubber apparatus (e.g., a wet scrubber apparatus, a dry scrubber apparatus). In additional embodiments, the effluent fluid treatment apparatus 146 is omitted (e.g., absent) from the material deposition system 100.

Thus, in accordance with embodiments of the disclosures, a material deposition system comprises a precursor source and a chemical vapor deposition apparatus in selective fluid communication with the precursor source. The precursor source configured to contain at least one metal-containing precursor material in one or more of a liquid state and a solid state. The chemical vapor deposition apparatus comprises a housing structure, a distribution manifold, and a substrate holder. The housing structure is configured and positioned to receive at least one feed fluid stream comprising the at least one metal-containing precursor material. The distribution manifold is within the housing structure and is in electrical communication with a signal generator. The substrate holder is within the housing structure, is spaced apart from the distribution assembly, and is in electrical communication with an additional signal generator.

During use and operation of the material deposition system 100, the substrate 126 may be delivered into the PECVD apparatus 104. The substrate 126 may be provided into the internal chamber 120 of the PECVD apparatus 104 by any desired means. In some embodiments, one or more conventional robotics apparatuses (e.g., robotic arms, robots) are employed to deliver the substrate 126 into the PECVD apparatus 104.

After delivering the substrate 126 into the PECVD apparatus 104, one or more feed fluid stream(s) 148 may be introduced into the internal chamber 120 of the PECVD apparatus 104 through one or more inlets in the housing structure 114 (e.g., in the sealable lid 122 of the housing structure 114). The feed fluid stream(s) 148 may include one or more precursor materials and/or derivatives thereof (e.g., ions produced from precursor materials from using the ionization device 112) from that precursor source 102. Optionally, the feed fluid stream(s) 148 may include one or more additional materials (e.g., carrier gases for the metal-containing precursor material(s)) as well. The materials of the received feed fluid stream(s) 148 may stabilize the internal chamber 120 at a desired operating pressure of the PECVD apparatus, such as an operating pressure within a range of from about 1 millitorr (mTorr) to about 50 mTorr (e.g., within a range of from about 1 mTorr to about 25, from about 5 mTorr to about 20 mTorr, or from about 10 mTorr to about 20 mTorr). The vacuum apparatus 142 (if any) of the material deposition system 100 may be employed to assist with maintaining the desired operating pressure of within the internal chamber 120 by controlling the flow of one or more effluent fluid streams 150 from the internal chamber 120 of the PECVD apparatus 104 through one or more outlets in the housing structure 114.

Next, one or more of the signal generators (e.g., one or more of the signal generator 124, the additional signal generator 132, and the further signal generator 136) may apply a voltage to one or more components of the PECVD apparatus 104 (e.g., one or more of the distribution assembly 116, the substrate holder 118, and the coil structure 134) to produce a plasma within the internal chamber 120 of the PEND apparatus 104 from materials (e.g., metal-containing precursor materials, derivatives thereof, inert gases) of the feed fluid stream(s) 148. In some embodiments, energy is directed to the distribution assembly 116 from the signal generator 124 and additional energy is directed to the substrate holder 118 from the additional signal generator 132 to produce the plasma within the internal chamber 120 of the PECVD apparatus 104. In some embodiments wherein the PECVD apparatus 104 includes the coil structure 134, further energy may be directed to the coil structure 134 from the further signal generator 136 to assist with creating, maintaining, and/or energizing the plasma.

As material from the feed fluid stream(s) 148 passes through the plasma and toward the substrate 126, at least some neutral units (e.g., atoms, molecules) of the material and/or ions (e.g., metal-containing ions, carbon-containing ions, boron-containing ions) formed from the material may react with one another, material (e.g., ions) of the plasma, and/or additional material(s) (e.g., additional metal-containing precursor material(s)) delivered into the PECVD apparatus 104 before reaching the substrate 126. In, addition embodiments, neutral units (e.g., atoms, molecules) of the material and/or ions (e.g., metal-containing ions, carbon-containing ions, boron-containing, ions) formed from the material pass through the plasma and toward the substrate 126 without substantially reacting with one another, material of the plasma, or additional material delivered into the PECVD apparatus 104.

Upon passing through the plasma, materials (e.g., reaction product materials, unreacted materials) may be deposited on, over, or within the substrate 126 to form a metal-containing material (e.g., a metal-containing carbon material, a metal-containing boron material, a metal-containing boron-carbon material) on, over, or within the substrate 126. The metal-containing material may comprise atoms of one or more of carbon and boron, and atoms of one or more metals (e.g., one or more of Ta, Hf, Zn, V, Ir, Zr, W, Nb, and Sc) of the precursor material(s) from the precursor source 102. By way of non-limiting example, the metal-containing material may be formed of and include one or more of M₁Cₓ, M₁M₂Cₓ, M₁Bₓ, M₁M₂Bₓ, M₁BₓC_{y}, M₁M₂BₓC_{y}, wherein M₁ and M₂ are individually metals selected from Ta, Hf, Zn, V, Ir, Zr, W, Nb, and Sc. Formulae including one or more of “x” and “y” herein (e.g., M₁Cₓ, M₁M₂Cₓ, M₁Bₓ, M₁M₂Bₓ, M₁BₓC_{y}, M₁M₂BₓC_{y}) represent a material that contains an average ratio of “x” atoms of one element and “y” atoms of an additional element (if any) for every one atom of another element (e.g., M₁, M₂). As the formulae are representative of relative atomic ratios and not strict chemical structure, the formed metal-containing material may comprise one or more stoichiometric compounds and/or one or more non-stoichiometric compounds, and values of “x” and “y” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In some embodiments, the metal-containing material comprises one or more of TaCₓ, VCₓ, NbCₓ, and TaHfCₓ. As described in further detail below, depending on the operating conditions (e.g., material(s), material flow rate(s), applied bias(es), bias continuity, operating pressure(s)) employed during the formation of the metal-containing material, the metal-containing material may exhibit a substantially homogenous distribution of the elements thereof (e.g., such that the elements are substantially uniformly distributed throughout the metal-containing material), or heterogeneous distribution of one or more of the elements thereof (e.g., such the one or more elements are non-uniformly distributed throughout one or more dimensions of the metal-containing material). The metal-containing material may be formed to have a desired thickness. In some embodiments, the metal-containing material is formed to have a thickness facilitating the use thereof as a hard mask material for subsequent etching processes (e.g., high aspect ratio (HAR) etching processes, such as cryogenic etching processes) to be performed on the substrate 126. By way of non-limiting example, the metal-containing material may be formed to have a thickness within a range of from about 2 micrometers (μm) to about 3 μm.

The type(s) and amount(s) of precursor material(s) and/or derivatives (e.g., metal-containing ions, carbon-containing ions, boron-containing ions) formed from the precursor material(s) directed into the PECVD apparatus 104 may be controlled (e.g., maintained, adjusted) during use and operation of the material deposition system 100 to control the amount and distribution of metal(s), carbon, and boron within the formed metal-containing material. By way of non-limiting example, the type(s) and/or amount(s) of precursor material(s) and/or derivatives formed from the precursor material(s) directed into the PECVD apparatus 104 may be controlled to control the types, amounts, and distributions of atoms (e.g., metal atoms, carbon atoms, boron atoms) within different regions (e.g., different vertical regions) of the formed metal-containing material. Accordingly, adjusting the one or more of the type(s) and amount(s) of precursor material(s) and/or derivatives formed therefrom may facilitate the formation of a metal-containing material exhibiting a heterogeneous distribution of one or more of metal(s), carbon, and boron throughout a height (e.g., vertical dimension) thereof.

The operating pressure of the PECVD apparatus 104 may also be controlled (e.g., maintained, adjusted) during use and operation of the material deposition system 100 to control characteristics of the metal-containing material formed on, over, or within the substrate 126. Increasing the operating pressure of the PECVD apparatus 104 may increase the frequency of collisions between plasma ions (e.g., noble gas ions, metal-containing ions, carbon-containing ions, boron-containing ions) and neutral units (e.g., carbon atoms, boron atoms, carbon-containing molecules, boron-containing molecules, metal atoms, metal-containing molecules) within the internal chamber 120 of the PECVD apparatus 104, to increase the amount time that material remains in (e.g., remains and reacts within) the plasma. As a result, a nearly isotropic directional distribution of material (e.g., reaction product material, unreacted material) may be formed on, over, or within the substrate 126. Conversely, decreasing the operating pressure of the PECVD apparatus 104 may decrease the frequency of collisions between plasma ions and neutral units within the internal chamber 120 of the PECVD apparatus 104, to decrease the amount time that the material remains in (e.g., remains and reacts within) the plasma. As a result, a relatively greater (as compared to the effects of relatively greater operating pressures) angular distribution of material (e.g., reaction product material, unreacted material) may be formed on, over, or within the substrate 126.

Application (or lack thereof) of bias to one or more components (e.g., one or more of the distribution assembly 116, the substrate holder 118, and the coil structure 134 (if any)) of the PECVD apparatus 104 may also be used to control characteristics of the metal-containing material formed on, over, or within the substrate 126. For example, biasing the distribution assembly 116 may attract plasma ions toward reactants (e.g., precursor(s), ions formed from precursor(s)) directed into the internal chamber 120 of the PECVD apparatus 104 to enhance collisions and reactions with and between the reactants. As another example, biasing the substrate holder 118 may attract the ionized deposition materials (e.g., ionized materials, such as ionized, reacted materials and/or ionized, unreacted materials) toward the substrate 126. Biasing the substrate holder 118 may attract the ionized deposition material toward the substrate 126 relatively more uniformly as compared to not biasing the substrate holder 118. Accordingly, bias may be applied to different components of the PECVD apparatus 104 at different times. For example, during a first phase of the process, power may be supplied from the signal generator 124 to the distribution assembly 116 while the substrate holder 118 is left is electrically neutral (e.g., no power is supplied from the additional signal generator 132 to the substrate holder 118); and during a second phase of the process, power may be supplied from the additional signal generator 132 to the substrate holder 118 while the distribution assembly 116 is left is electrically neutral (e.g., no power is supplied from the signal generator 124 to the distribution assembly 116). As another example, during a first phase of the process, power may be supplied from the signal generator 124 to the distribution assembly 116 while the substrate holder 118 is left is electrically neutral; and during a second phase of the process, the distribution assembly 116 and the substrate holder 118 may both be left electrically neutral. As a further example, during a first phase of the process, power may be supplied from the signal generator 124 to the distribution assembly 116 while the substrate holder 118 is left is electrically neutral; during a second phase of the process, the distribution assembly 116 and the substrate holder 118 may both be left electrically neutral; and during a third phase of the process, power may be supplied from the additional signal generator 132 to the substrate holder 118 while the distribution assembly 116 is left is electrically neutral.

The continuity (or discontinuity) of bias applied to a given component of the (e.g., the distribution assembly 116, the substrate holder 118, and the coil structure 134) of the PECVD apparatus 104 over a given period of time may also be used to control characteristics of the metal-containing material formed on, over, or within the substrate 126. Pulsed signals (e.g., a pulsed RF (PRF) signal, a pulsed DC (PDC) signal) may be employed to bias different components of the PECVD apparatus 104, and/or non-pulsed signals (e.g., continuous signals, such as a continuous RF signal, a continuous DC signal) employed to bias different components of the PECVD apparatus 104. In some embodiments, pulsed signals including bursts of current (e.g., RF current, DC) are employed to bias one or more components of the PECVD apparatus 104. Pulsing the applied current may, for example, facilitate heat dissipation during the silent period. If pulsed signals are employed, the duty cycle (ti/Ti, wherein ti is the pulse width and Ti is the frequency at which the signal is pulsed or modulated) of the applied bias waveform may be controlled to facilitate desirable characteristics in the metal-containing material formed on, over, or within the substrate 126. For example, increasing the duty cycle of a bias waveform applied to one or more of the substrate holder 118 and the distribution assembly 116 may reduce (or even eliminate) undesirable impurities and/or void spaces within the metal-containing material.

During and/or after the formation of the metal-containing material on, over, or within the substrate 126 exhaust gases including unreacted materials (e.g., precursor materials, noble gases, noble gas ions, metal atoms, metal-containing molecules, metal-containing ions, carbon atoms, carbon-containing molecules, carbon-containing ions, boron atoms-boron-containing molecules, boron-containing ions, carrier gases) and/or reaction byproducts may exit the PECVD apparatus 104. At least one effluent fluid stream 150 including the unreacted materials and/or reaction byproducts may then be directed (e.g., by way of the flow path switching device 144) to one or more additional apparatuses (e.g., the effluent fluid treatment apparatus 146) and further treated, utilized, and/or disposed of, as desired.

Prior to and/or following the formation of the metal-containing material on, over, or within the substrate 126, the PECVD apparatus 104 may be subjected to at least one chamber cleaning process to remove one or more materials (e.g., contaminant materials; residual materials, such as one or more of residual unreacted materials, residual reaction product materials, and residual reaction byproduct materials) from surfaces of the PECVD apparatus 104 within the internal chamber 120. The chamber cleaning process may include directing one or more chamber cleaning fluid stream(s) 152 (e.g., one or more gaseous chamber cleaning fluid streams) into the internal chamber 120 of the PECVD apparatus 104 through one or more inlets in the housing structure 114 (e.g., in the lid 122 of the housing structure 114). The chamber cleaning fluid stream(s) 152 may include one or more chamber cleaning materials from the chamber cleaning material source 138 and/or derivatives thereof (e.g., ions produced from the chamber cleaning materials by way of the additional ionization device 140).

Within the internal chamber 120, the chamber cleaning materials and/or derivatives thereof may interact with and remove undesired materials from surfaces of the PECVD apparatus 104. The chamber cleaning process may be effectuated with or without the production of plasma (e.g., using voltage applied to one or more of the distribution assembly 116, the substrate holder 118, and the coil structure 134) within the internal chamber 120 of the PECVD apparatus 104 (e.g., from the chamber cleaning materials and/or derivatives thereof).

During and/or after the removal of undesired materials from surfaces of the PECVD apparatus 104 within the internal chamber 120, exhaust gases including unreacted materials (e.g., chamber cleaning materials, unreacted ions formed from chamber cleaning materials) and/or reaction products may exit the PECVD apparatus 104. At least one effluent cleaning fluid stream 154 including the unreacted materials and/or reaction products may then be directed (e.g., by way of the flow path switching device 144) to one or more additional apparatuses (e.g., the chamber cleaning material source 138, another apparatus) and further treated, utilized, and/or disposed of, as desired.

Thus, in accordance with embodiments of the disclosure, a method of forming a microelectronic device comprises directing a feed fluid stream into a chemical vapor deposition apparatus containing a base structure. The feed fluid stream comprising at least one metal-containing precursor material in one or more of a liquid state and a solid state. A plasma is formed within the chemical vapor deposition apparatus using the at least one feed fluid stream. A metal-containing material is formed over the base structure using the plasma.

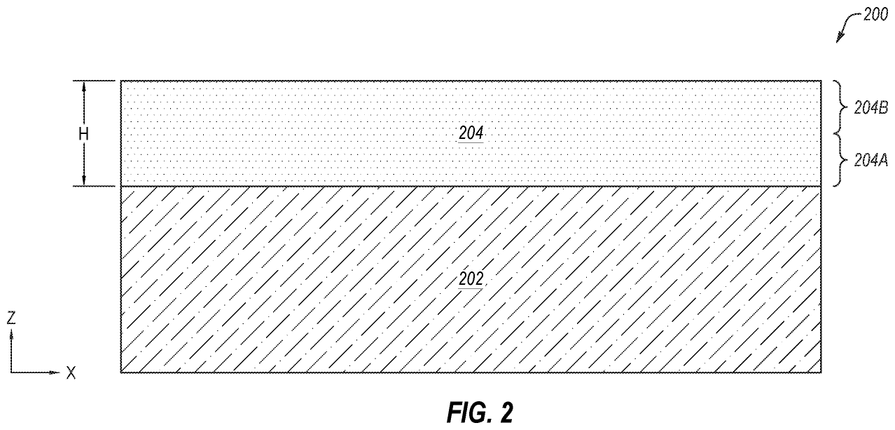

FIG. 2 illustrates a simplified, partial cross-sectional view of a microelectronic device structure 200 that may formed using the material deposition system 100 and the methods previously described with reference to FIG. 1, in accordance with embodiments of the disclosure. The microelectronic device structure 200 may be employed within a microelectronic device of the disclosure and/or maybe employed to form a microelectronic device of the disclosure. As shown in FIG. 2, the microelectronic device structure 200 may include a base structure 202 and a metal-containing material 204 on or over the base structure 202. The base structure 202 may correspond to the substrate 126 previously described with reference to FIG. 1, and the metal-containing material 204 may correspond to the metal-containing material formed over the substrate 126 using the PECVD process previously described with reference to FIG. 1. In some embodiments, the metal-containing material 204 comprises one or more of M₁Cₓ, M₁M₂Cₓ, M₁Bₓ, M₁M₂Bₓ, M₁BₓC_{y}, M₁M₂BₓC_{y}, wherein M₁ and M₂ are individually metals selected from Ta, Hf, Zn, V, Ir, Zr, W, Nb, and Sc.

As shown in FIG. 2, the metal-containing material 204 may be formed to include a region 204A over the base structure 202, and at least one additional region 204B over the region 204A. The additional region 204B may be formed to be substantially similar to (e.g., to have substantially the same material composition, material distributions, and thickness) the region 204A, or may be formed to be different (e.g., to have a different material composition, a different material distributions, and/or a different thickness) than the region 204A. In some embodiments, the region 204A and the additional region 204B each individually comprise atoms of one or more of B and C, and atoms of one or more of Ta, Hf, Zn, V, Ir, Zr, W, Nb, and Sc. The region 204A and the additional region 204B may each individually be substantially free of void spaces and/or elements other than the B, C, Ta, Hf, Zn, V, Ir, Zr, W, Nb, and Sc.

In some embodiments, the region 204A and the additional region 204B of the metal-containing material 204 are each individually formed to exhibit a substantially homogenous distribution of elements (e.g., metal(s), such as one or more of Ta, Hf, Zn, V, Ir, Zr, W, Nb, and Sc; other elements, such as one or more of C and B) thereof, such that the elements of the region 204A and the additional region 204B are substantially uniformly distributed throughout the region 204A and the additional region 204B. In additional embodiments, at least one of the region 204A and the additional region 204B of the metal-containing material 204 is/are formed to exhibit a heterogeneous distribution of one or more element(s) thereof, such that the element(s) of region 204A and/or the additional region 204B are non-uniformly distributed throughout the region 204A and/or the additional region 204B. For example, the region 204A and the additional region 204B may each exhibit a heterogeneous distribution of the metal(s) thereof. In such embodiments, amounts of the metal(s) may vary throughout thicknesses (e.g., vertical dimensions in the Z-direction) of the region 204A and/or the additional region 204B. If the region 204A and/or the additional region 204B exhibit a heterogeneous distribution of element(s) thereof, amounts of the element(s) may vary stepwise (e.g., change abruptly), or may vary continuously (e.g., change progressively, such as linearly or parabolically) throughout the thickness(es) of the region 204A and/or the additional region 204B.

The metal-containing material 204 (including the different vertical regions thereof, such as the region 204A and the additional region 204B) may exhibit a desired height H (e.g., overall vertical dimension in the Z-direction). The height H of the metal-containing material 204 may be selected at least partially based on a desired function of the metal-containing material 204. By way of non-limiting example, in some embodiments wherein the metal-containing material 204 functions as a hard mask material for subsequent HAR etching processes (e.g., cryogenic etching processes) to form HAR structures (e.g., structures having a height to width ratio greater than or equal to about 5:1, such as greater than or equal to 10:1, greater than or equal to 25:1, greater than or equal to 50:1, greater than or equal to 100:1, or within a range of from about 5:1 to about 100:1) from portions of the base structure 202, metal-containing material 204 may be formed to have a height H within a range of from about 2 micrometers (μm) to about 3 μm.

Thus, in accordance with embodiments of the disclosure, a microelectronic device comprises a microelectronic device structure comprising a metal-containing material formed through plasma-enhanced chemical vapor deposition overlying a base structure. The metal-containing material comprises one or more of M₁Cₓ, M₁M₂Cₓ, M₁Bₓ, M₁M₂Bₓ, M₁BₓC_{y}, and M₁M₂BₓC_{y} over the base structure, wherein M₁ and M₂ are individually metals selected from Ta, Hf, Zn, V, Ir, Zr, W, Nb, and Sc.

Following the formation of the metal-containing material 204, the microelectronic device structure 200 may be subjected to further processing, as desired. In some embodiments, the microelectronic device structure 200 is subject to at least one etching process to form HAR structures from portions of the base structure 202 using one or more portions of the metal-containing material 204 as a hard mask. For example, the microelectronic device structure 200 may be subjected to at least one cryogenic etching process to form the HAR structures using the metal-containing material 204 as a hard mask. The metal-containing material 204 may alleviate many problems associated forming HAR structures using conventional hard mask materials. For example, the metal-containing material 204 may be thinner than conventional hard mask materials, may have improved stress characteristics as compared to conventional hard mask materials, and/or may require less processing for the formation and/or use thereof as compared to conventional hard mask materials.

Thus, in accordance with embodiments of the disclosure, a method of forming a microelectronic device comprises forming a metal-containing material over a base structure through plasma enhanced chemical deposition. The metal-containing material comprises one or more of carbon and boron; and one or more of tantalum, hafnium, zinc, vanadium, iridium, zirconium, tungsten, niobium, and scandium. The base structure is etched using the metal-containing material as a hard mask.

The material deposition systems (e.g., the material deposition system 100 (FIG. 1)), methods, microelectronic device structures (e.g., the microelectronic device structure 200 (FIG. 2)), and microelectronic devices of the disclosure facilitate reduced costs (e.g., manufacturing costs, material costs), increased miniaturization of components, improved performance, and greater packaging density as compared to conventional material deposition systems, conventional methods, conventional microelectronic device structures, conventional microelectronic devices, and conventional electronic systems. The material deposition systems, methods, microelectronic device structures, and microelectronic devices of the disclosure may improve scalability, efficiency, and simplicity as compared to conventional material deposition systems, conventional methods, conventional microelectronic device structures, and conventional microelectronic devices.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

1. A material deposition system, comprising:
a precursor source configured to contain at least one metal-containing precursor material in one or more of a liquid state and a solid state; and
a chemical vapor deposition apparatus in selective fluid communication with the precursor source and comprising:
a housing structure configured and positioned to receive at least one feed fluid stream comprising the at least one metal-containing precursor material;
a distribution manifold within the housing structure and in electrical communication with a signal generator; and
a substrate holder within the housing structure and spaced apart from the distribution manifold, the substrate holder in electrical communication with an additional signal generator.

2. The material deposition system of claim 1, further comprising an ionization device downstream of the precursor source and upstream of the chemical vapor deposition apparatus, the ionization device configured to at least partially ionize the at least one metal-containing precursor material.

3. The material deposition system of claim 2, further comprising:
a chamber cleaning material source configured to contain at least one chamber cleaning material; and
an additional ionization device downstream of the chamber cleaning material source and upstream of the chemical vapor deposition apparatus, the additional ionization device configured to at least partially ionize the at least one chamber cleaning material.

4. The material deposition system of claim 3, wherein the ionization device and the additional ionization device are spaced apart from one another on a sealable lid of the housing structure.

5. The material deposition system of claim 1, wherein the precursor source is configured to contain a flowable solid form of the at least one metal-containing precursor material, and is positioned on or over a sealable lid of the housing structure.

6. The material deposition system of claim 1, wherein the precursor source is configured to contain a liquid form of the at least one metal-containing precursor material, and is in selective fluid communication with the chemical vapor deposition apparatus by way of an insulated line.

7. The material deposition system of claim 1, further comprising a heating apparatus configured and positioned to heat the precursor source.

8. The material deposition system of claim 1, further comprising an effluent fluid treatment apparatus downstream of the chemical vapor deposition apparatus, the effluent fluid treatment apparatus configured to remove one or more materials from at least one effluent fluid stream exiting the housing structure of the chemical vapor deposition apparatus.

9. The material deposition system of claim 8, further comprising a bypass apparatus downstream of the chemical vapor deposition apparatus and upstream of the effluent fluid treatment apparatus.

10. The material deposition system of claim 1, further comprising a carrier gas source in selective fluid communication with the precursor source.

11. The material deposition system of claim 1, wherein the chemical vapor deposition apparatus further comprises a coil structure between the distribution manifold and the substrate holder and in electrical communication with another signal generator.

12. A method of forming a microelectronic device, comprising:
directing a feed fluid stream into a chemical vapor deposition apparatus containing a base structure, the feed fluid stream comprising at least one metal-containing precursor material in one or more of a liquid state and a solid state;
forming a plasma within the chemical vapor deposition apparatus using the at least one feed fluid stream; and
forming a metal-containing material over the base structure using the plasma.

13. The method of claim 12, further comprising selecting the at least one metal-containing precursor material to comprise one or more of a tantalum-containing precursor material, a hafnium-containing precursor material, a zinc-containing precursor material, a vanadium-containing precursor material, an iridium-containing precursor material, a zirconium-containing precursor material, a tungsten-containing precursor material, a niobium-containing precursor material, and a scandium-containing precursor material.

14. The method of claim 12, further comprising selecting the at least one metal-containing precursor material to comprise:
one or more of boron and carbon; and
one or more of tantalum, hafnium, zinc, vanadium, iridium, zirconium, tungsten, niobium, and scandium.

15. The method of claim 12, further comprising forming the feed fluid stream to comprise one or more of liquid droplets and solid particles of the at least one metal-containing precursor suspended in a carrier gas.

16. The method of claim 12, wherein forming a plasma within the chemical vapor deposition apparatus comprises applying a voltage to one or more of a distribution manifold, a substrate holder offset from the distribution manifold, and a coil structure between the distribution manifold and the substrate holder to form the plasma from components of the at least one feed fluid stream.

17. The method of claim 12, further comprising ionizing at least a portion of the at least one metal-containing precursor material of the feed fluid stream prior to directing the feed fluid stream into the chemical vapor deposition apparatus.

18. The method of claim 12, wherein forming a metal-containing material over the base structure using the plasma comprises forming one or more of a metal-containing boride material, a metal-containing carbide material, and a metal-containing boron carbide material over the base structure using the plasma.

19. The method of claim 12, further comprising capturing one or more of unreacted precursors of the at least one metal-containing precursor material and reaction byproducts from the formation of the metal-containing material in at least one effluent fluid treatment apparatus downstream of the chemical vapor deposition apparatus.

20. A microelectronic device, comprising a microelectronic device structure comprising a metal-containing material formed through plasma-enhanced chemical vapor deposition overlying a base structure, the metal-containing material comprising one or more of M₁Cₓ, M₁M₂Cₓ, M₁Bₓ, M₁M₂Bₓ, M₁BₓC_{y}, and M₁M₂BₓC_{y} over the base structure, wherein M₁ and M₂ are individually metals selected from Ta, Hf, Zn, V, Ir, Zr, W, Nb, and Sc.

21. The microelectronic device of claim 20, wherein the metal-containing material has a thickness within a range of from about 2 micrometers to about 3 micrometers.

22. The microelectronic device of claim 20, wherein metal-containing material has a heterogeneous distribution of one or more elements thereof.

23. A method of forming a microelectronic device, comprising:
forming a metal-containing material over a base structure through plasma enhanced chemical deposition, the metal-containing material comprising:
one or more of carbon and boron; and
one or more of tantalum, hafnium, zinc, vanadium, iridium, zirconium, tungsten, niobium, and scandium; and
etching the base structure using the metal-containing material as a hard mask.

24. The method of claim 23, wherein forming a metal-containing material over a base structure comprises forming one or more of M₁Cₓ, M₁M₂Cₓ, M₁Bₓ, M₁M₂Bₓ, M₁BₓC_{y}, and M₁M₂BₓC_{y} over the base structure, wherein M₁ and M₂ are individually metals selected from Ta, Hf, Zn, V, Ir, Zr, W, Nb, and Sc.

25. The method of claim 23, wherein etching the base structure using the metal-containing material as a hard mask comprises cryogenically etching the base structure.

26. The method of claim 23, wherein etching the base structure using the metal-containing material as a hard mask comprises forming high aspect ratio structures from portions of the base structure, the high aspect ratio structures individually having an aspect ratio within a range of from about 5:1 to about 100:1.
